(19) United States
(12) Patent Application Publication
(10) Pub. No.: US 2013/0032685 A1
(43) Pub. Date: Feb. 7, 2013

(54) MOUNTING APPARATUS FOR DISK DRIVE

(71) Applicants: CHAO LIU, Wuhan City (CN); ZHI-PING WU, Wuhan City (CN); XU-DONG NAN, Wuhan City (CN)

(72) Inventors: CHAO LIU, Wuhan City (CN); ZHI-PING WU, Wuhan City (CN); XU-DONG NAN, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/484,578

(22) Filed: May 31, 2012

(30) Foreign Application Priority Data
Aug. 3, 2011 (CN) 201110220885.2

(51) Int. Cl. H05K 7/00

(52) U.S. Cl. 248/310

(57) ABSTRACT

A mounting apparatus includes a bracket and a base. The bracket includes a first side plate and a second side plate opposite to the first side plate. A flange extends from the first side plate. The flange defines a securing opening. A first hook extends from the second side plate. A latching portion protrudes from the flange. The base includes a bottom wall and a sidewall connected to the bottom wall. A first blocking portion is located on the bottom wall. A second hook extends from the sidewall. The bottom wall defines an guiding slot and a latching slot communicating with the guiding slot, and the latching portion is engaged in the latching slot through the guiding slot; the first blocking portion is received in the securing opening; and the first hook is engaged with the second hook.

### BACKGROUND

1. Technical Field

The present disclosure relates to mounting apparatuses, and particularly to a mounting apparatus for a disk drive.

2. Description of Related Art

Many disk drives are secured in a drive bracket. The drive bracket defines a number of through holes, and each disk drive defines a number of fastening holes. In assembly, the disk drive is inserted in the drive bracket, and the fastening holes are aligned with the through holes. A number of screws are secured into the fastening holes through the through holes, to secure the disk drive to the drive bracket. Removal and installation of the disk drive may be laborious and inconvenient. Therefore, an improved mounting device for the disk drive is desired within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus in accordance with an embodiment.

FIG. 2 is similar to FIG. 1, but viewed from a different aspect.

FIG. 3 is an enlarged view of a circled portion III of FIG. 1.

FIG. 4 is an assembled, isometric view of the mounting apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

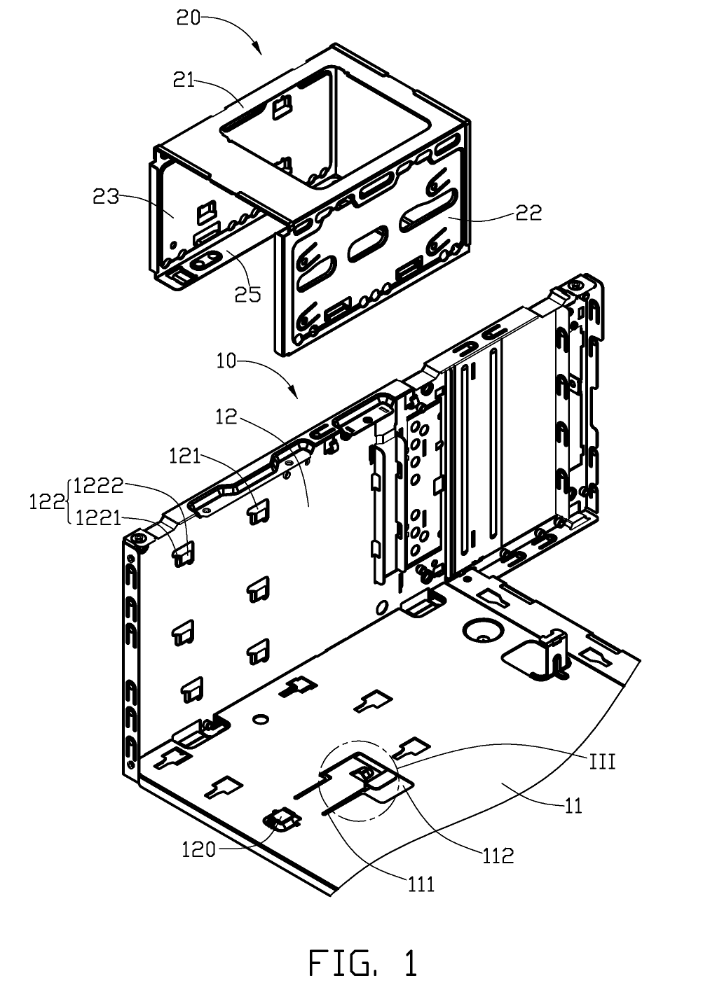

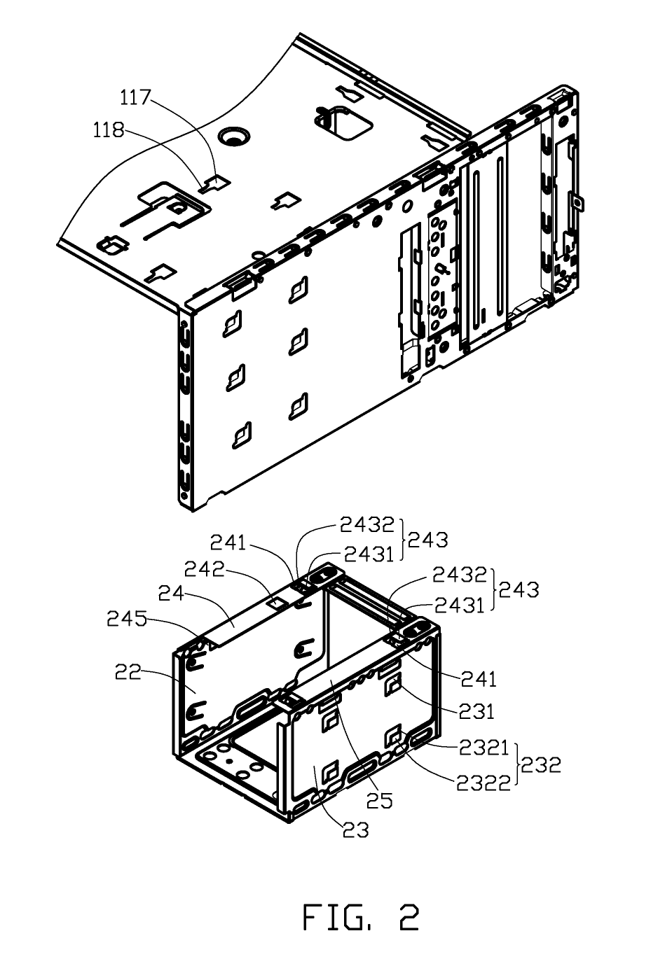

FIG. 1 and FIG. 2 show a mounting apparatus in accordance with an embodiment. The mounting apparatus includes a base 10 and a bracket 20.

The bracket 20 includes a top plate 21, a first side plate 22, and a second side plate 23. The first side plate 22 and the second side plate 23 extend from two opposite sides of the top plate 21. In one embodiment, the first side plate 22 and the second side plate 23 are substantially perpendicular to the top plate 21. A first flange 24 extends perpendicularly from a bottom edge of the first side plate 22. A second flange 25 extends perpendicularly from a bottom edge of the second side plate 23. The second side plate 23 defines a plurality of first openings 231. A first hook 232 is located in each of the plurality of first openings 231. The first hook 232 includes two first connecting pieces 2321 and a first limiting piece 2322. The two first connecting pieces 2321 extend from two adjacent edges of each of the plurality of first openings 231. The first limiting piece 2322 is connected to the two first connecting pieces 2321.

Each of the first flange 24 and the second flange 25 defines at least one latching opening 241. A latching portion 243 extends out of the latching opening 241. The latching portion 243 includes a first positioning piece 2431 and a first latching piece 2432. The first positioning piece 2431 extends outwards from a first edge of the latching opening 241. The first latching piece 2432 extends from a second edge of the latching opening 241 and is connected to the first positioning piece 2431. The second edge of the latching opening 241 is opposite to the first edge of the latch opening 241. A width of the first positioning piece 2431 is greater than a width of the first latching piece 2432. The first flange 24 further defines a securing opening 242 and a cutout 245. In one embodiment, the securing opening 242 is rectangular.

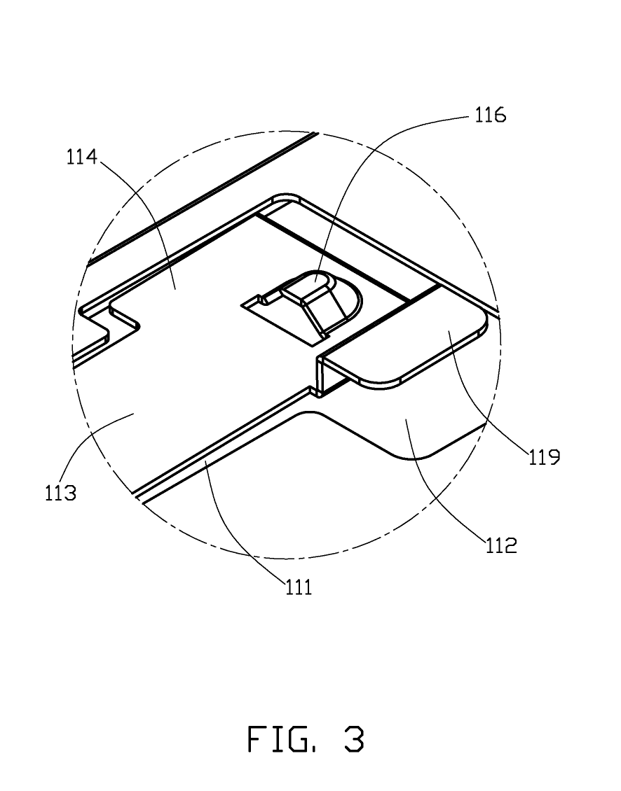

FIG. 1 and FIG. 3 show the base 10 including a bottom wall 11 and a sidewall 12 extending from the bottom wall 11. In one embodiment, the sidewall 12 is substantially perpendicular to the bottom wall 11. The bottom wall 11 defines a first receiving opening 111 and a second receiving opening 112 communicating with the first receiving opening 111. A first resilient piece 113 extends from a side edge of the first receiving opening 111 towards the second receiving opening 112 and is located in the first receiving opening 111. A second resilient piece 114 extends from the first resilient piece 113 and is located in the second receiving opening 112. A width of the first receiving opening 111 is smaller than a width of the second receiving opening 112. A width of the first resilient piece 113 is smaller than a width of the second resilient piece 114. A first blocking portion 116 protrudes from the second resilient piece 114. The first blocking portion 116 corresponds to the securing opening 242. An operating piece 119 extends upwards from a side edge of the second resilient piece 114 and is operable to elastically deform the first resilient piece 113 and the second resilient piece 114.

FIG. 2 shows the bottom wall 11 further defines a plurality of guiding slots 117 and a plurality of securing slots 118. Each of the plurality of guiding slots 117 communicates with one of the plurality of securing slots 118. A width of each guiding slot 117 is greater than a width of each securing slot 118. A second blocking portion 120 protrudes from the bottom wall 11. The second blocking portion 120 corresponds to the cutout 245. The side wall 12 defines a plurality of second openings 121. A second hook 122 is located in each of the plurality of second openings 121. The second hook 122 includes two second connecting pieces 1221 and a second limiting piece 1222. The two second connecting pieces 1221 extend from two adjacent edges of each of the plurality of second openings 121. The second limiting piece 1222 is connected to the two second connecting pieces 1221.

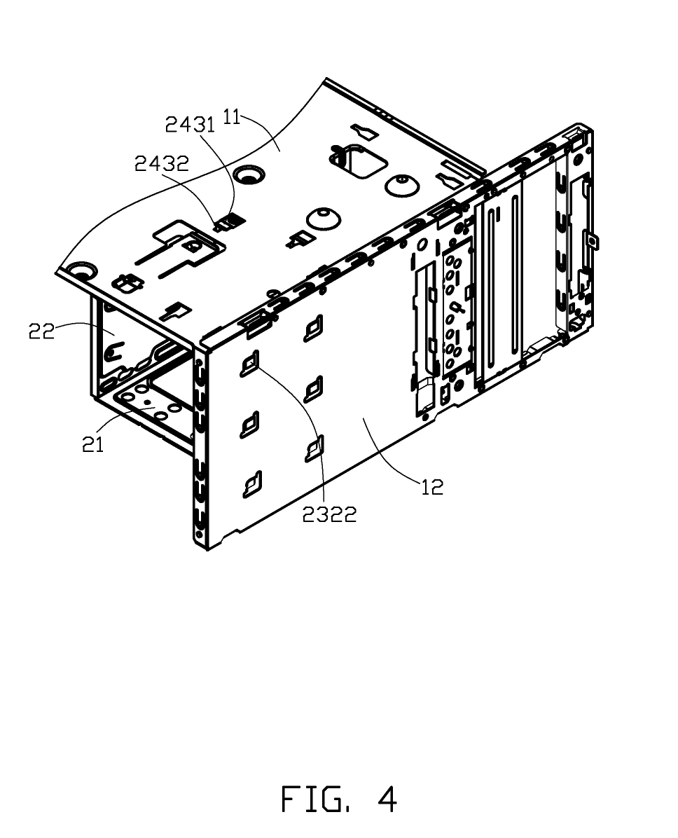

FIG. 4 shows that, in assembly, the bracket 20 is placed on the bottom wall 11, and the first limiting piece 2322 is aligned with the second opening 121, and the latching portion 243 is inserted into the guiding slot 117. The first resilient piece 113 and the second resilient piece 114 are located below the first flange 24 and blocked and elastically deformed downwards. The bracket 20 is moved towards the second blocking portion 120 until the bracket 20 is blocked by the second blocking portion 120, and the first blocking portion 116 is aligned with the securing opening 242. The second blocking portion 120 is received in the cutout 245. The first resilient piece 113 and the second resilient piece 114 rebound to engage the first blocking portion 116 in the securing opening 242. The first hook 232 is engaged with the second hook 122; and the latching piece 2432 is engaged in the latching slot 118. The first limiting piece 2322 is located between the second limiting piece 1222 and the side wall 12, and the second limiting piece 1222 is located between the first limiting piece 2322 and the first side plate 23. Thus, the bracket 20 is secured to the base 10.

In disassembly, the operating piece 119 is pushed downwards to elastically deform the first resilient piece 113 and the second resilient piece 114, until the first blocking portion 116 is disengaged from the securing opening 242. The bracket 20 is moved away from the second blocking portion 120, the first hook 232 is disengaged from the second hook 122, and the latching portion 243 is disengaged from the latching slot 118 and located in the guiding slot 117. The bracket 20 can be removed upwards from the base 10.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A mounting apparatus comprising:
a bracket comprising a first side plate, a second side plate opposite to the first side plate, a flange extending from the first side plate, a first hook extending from the second side plate, and a latching portion protruding from the flange; and
a base comprising a bottom wall, a sidewall connected to the bottom wall, a first blocking portion located on the bottom wall, and a second hook extending from the sidewall;
wherein the flange defines a securing opening; the bottom wall defines a guiding slot and a latching slot communicating with the guiding slot; the latching portion is engaged in the latching slot through the guiding slot; the first blocking portion is received in the securing opening; and the first hook is engaged with the second hook.

2. The mounting apparatus of claim 1, wherein the second side plate defines a first opening, and the sidewall defines a second opening; the first hook comprises two first connecting pieces and a first limiting piece, the two first connecting pieces extend from two adjacent edges of the first opening, and the first limiting piece connects the two first connecting pieces; the second hook comprises two second connecting pieces and a second limiting piece, the two second connecting piece extend from two adjacent edges of the second opening, and the second limiting piece connects the two second connecting pieces; and the first limiting piece is secured between the second limiting piece and the sidewall.

3. The mounting apparatus of claim 2, wherein the second limiting piece is secured between the limiting piece and the second side plate.

4. The mounting apparatus of claim 1, wherein a width of the guiding slot is greater than a width of the latching slot.

5. The mounting apparatus of claim 4, wherein the flange further defines a latching opening; the latching portion comprises a positioning piece and a latching piece connected to the positioning piece, the positioning piece extends from a first edge of the latching opening, and the latching piece extends from a second edge of the latching opening; the second edge of the latching opening is opposite to the first edge of the latching opening; a width of the positioning piece is greater than a width of the latching piece and smaller than the width of the guiding slot, and the width of the latching piece is substantially equal to the width of the latching slot.

6. The mounting apparatus of claim 1, wherein the bottom wall further defines a first receiving opening and a second receiving opening communicating with the first receiving opening, a first resilient piece extends from an edge of the first receiving opening towards the second receiving opening, and a second resilient piece extends from the first resilient piece; and the first blocking portion extends from the second resilient piece.

7. The mounting apparatus of claim 6, wherein a width of the second receiving opening is greater than a width of the first receiving opening, and a width of the second resilient piece is greater than a width of the first resilient piece.

8. The mounting apparatus of claim 6, wherein the first resilient piece is received in the first receiving opening, and the second resilient piece is received in the second receiving opening.

9. The mounting apparatus of claim 6, wherein an operating piece extends upwards from a side edge of the second resilient piece, the operating piece is operable to elastically deform the first resilient piece and the second resilient piece, and the bracket is located between the sidewall and the operating piece.

10. The mounting apparatus of claim 1, wherein the base further comprises a second blocking portion protruding from the bottom wall; the flange defines a cutout; the second blocking portion is received in the cutout; and the blocking portion abuts a side edge of the flange.

11. A mounting apparatus comprising:
a bracket comprising a first side plate, a second side plate opposite to the first side plate, a flange extending from the first side plate, a first hook extending from the second side plate, and a latching portion protruding from the flange; and
a base comprising a bottom wall, a sidewall connected to the bottom wall, a first resilient piece and a second resilient piece located on the bottom wall, a second blocking portion protruding from the second resilient piece, and a second hook extending from the sidewall;
wherein the flange defines a securing opening and a cutout; the second resilient piece extends from the first resilient piece, and a first blocking portion protrudes from the second resilient piece; the first blocking portion is received in the securing opening, and the first resilient piece and the second resilient piece are elastically deformable to disengage the first blocking portion from the securing opening; the second blocking portion is received in the cutout, and a side edge of the flange abuts the second blocking portion; the bottom wall defines an guiding slot and a latching slot communicating with the guiding slot, and the latching portion is engaged in the latching slot through the guiding slot; the first hook is engaged with the second hook.

12. The mounting apparatus of claim 11, wherein the second side plate defines a first opening, and the sidewall defines a second opening; the first hook comprises two first connecting pieces and a first limiting piece, the two first connecting pieces extend from two adjacent edges of the first opening, and the first limiting piece connects the two first connecting pieces; the second hook comprises two second connecting pieces and a second limiting piece, the two second connecting pieces extend from two adjacent edges of the second opening, and the second limiting piece connects the two second connecting pieces;
and the first limiting piece is secured between the second limiting piece and the sidewall.

13. The mounting apparatus of claim 12, wherein the second limiting piece is secured between the limiting piece and the second side plate.

14. The mounting apparatus of claim 11, wherein a width of the guiding slot is greater than a width of the latching slot.

15. The mounting apparatus of claim 14, wherein the flange further defines a latching opening; the latching portion comprises a positioning piece and a latching piece connected to the positioning piece, the positioning piece extends from a first edge of the latching opening, and the latching piece extends from a second edge of the latching opening; the second edge of the latching opening is opposite to the first edge of the latching opening; a width of the positioning piece is greater than a width of the latching piece and smaller than the width of the guiding slot, and the width of the latching piece is substantially equal to the width of the latching slot.

16. The mounting apparatus of claim 11, wherein the bottom wall further defines a first receiving opening and a second receiving opening communicating with the first receiving opening, and the first resilient piece extends from an edge of the first receiving opening towards the second receiving opening.

17. The mounting apparatus of claim 16, wherein a width of the second receiving opening is greater than a width of the first receiving opening, and a width of the second resilient piece is greater than a width of the first resilient piece.

18. The mounting apparatus of claim 16, wherein the first resilient piece is received in the first receiving opening, and the second resilient piece is received in the second receiving opening.

19. The mounting apparatus of claim 11, wherein an operating piece extends upwards from a side edge of the second resilient piece, the operating piece is operable to elastically deform the first resilient piece and the second resilient piece, and the bracket is located between the sidewall and the operating piece.

20. The mounting apparatus of claim 11, wherein the flange is substantially perpendicular to the first side plate and the second side plate.
